(19) United States
(12) Patent Application Publication
(10) Pub. No.: US 2026/0323848 A1
(43) Pub. Date: Oct. 15, 2026

(54) DISPLAY DEVICE

(71) Applicant: BOE TECHNOLOGY GROUP CO., LTD., Beijing (CN)

(72) Inventors: Junhuan LIU, Beijing (CN); Hong ZHU, Beijing (CN); Sitong CHEN, Beijing (CN); Boyang SHI, Beijing (CN)

(73) Assignee: BOE TECHNOLOGY GROUP CO., LTD., Beijing (CN)

(21) Appl. No.: 19/146,529

(22) PCT Filed: Aug. 27, 2024
(86) PCT No.: PCT/CN2024/114934

§ 371 Date: Jul. 9, 2025

(30) Foreign Application Priority Data
Apr. 12, 2024 (CN) 202410445780.4

(51) Int. Cl. H05K 5/02

(52) U.S. Cl. CPC H05K 5/0217

(57) ABSTRACT

A display device includes a reel, a flexible display panel and a printed circuit board. The reel has an accommodating cavity and an opening that are in communication. The reel includes a shaft housing and a support member that are connected; and at least a portion of the support member is opposite to an inner side of the shaft housing. A starting section of the flexible display panel is located between the inner side of the shaft housing and the support member. The flexible display panel extends from an interior of the accommodating cavity through the opening to an exterior of the accommodating cavity and is wound around an outer side of the shaft housing. The starting section of the flexible display panel is connected to the support member. The printed circuit board is located in the accommodating cavity, and connected to the flexible display panel.

### CROSS-REFERENCE TO RELATED APPLICATIONS

This application is a national phase entry under 35 USC 371 of International Patent Application No. PCT/CN2024/114934, filed on Aug. 27, 2024, which claims priority to Chinese Patent Application No. 202410445780.4, filed on Apr. 12, 2024, each are incorporated herein by reference in their entirety.

### TECHNICAL FIELD

The present disclosure relates to the field of display technologies, and in particular, to a display device.

### BACKGROUND

With expansion of market demand for flexible displays, research and development of various flexible display devices are receiving increasing attention. For example, a rollable display device that has been developed and used includes a flexible display panel and a reel, and the flexible display panel is rolled up or unrolled on the reel.

The display device further includes a printed circuit board. The printed circuit board is usually provided outside the reel. Since the printed circuit board is not rollable, the printed circuit board cannot be wound on the reel. The display device has a large area that cannot be rolled up, which may affect a storage effect of the display device.

### SUMMARY

A display device is provided. The display device includes a reel, a flexible display panel and a printed circuit board. The reel has an accommodating cavity and an opening. The accommodating cavity and the opening are in communication. The reel includes a shaft housing and a support member. The support member is connected to the shaft housing; and at least a portion of the support member is opposite to an inner side of the shaft housing. A starting section of the flexible display panel is located between the inner side of the shaft housing and the support member. The flexible display panel extends from an interior of the accommodating cavity through the opening to an exterior of the accommodating cavity and is wound around an outer side of the shaft housing. The starting section of the flexible display panel is connected to the support member. The printed circuit board is located in the accommodating cavity; and the printed circuit board is connected to the flexible display panel.

In some embodiments, one side of the starting section of the flexible display panel is connected to the support member, and another side thereof is connected to the inner side of the shaft housing.

In some embodiments, the support member and the shaft housing press the starting section of the flexible display panel.

In some embodiments, the inner side of the shaft housing is provided with a protective layer thereon, and the protective layer is at least disposed opposite to the starting section of the flexible display panel.

In some embodiments, a dimension of the opening in a length direction of the reel is greater than a dimension of the flexible display panel in the length direction of the reel; and/or a width of the opening is greater than or equal to a thickness of the flexible display panel.

In some embodiments, a surface of the support member proximate to the flexible display panel includes a connection area and a transition area. The connection area is connected to the flexible display panel, and the connection area is in a shape of a planar face or a curved face. The transition area is located at the opening, and the transition area is in a shape of a curved face.

In some embodiments, the outer side of the shaft housing is in a shape of a curved face, and a radius of curvature of the transition area is smaller than a radius of curvature of the outer side of the shaft housing.

In some embodiments, a surface of the support member proximate to the flexible display panel is provided with a protrusion thereon, and an end portion of the flexible display panel is located between the protrusion and the opening.

In some embodiments, the starting section of the flexible display panel, the support member and the printed circuit board are stacked in sequence.

In some embodiments, the printed circuit board is further connected to the support member.

In some embodiments, the display device further includes a reinforcing plate. The reinforcing plate is disposed on a side of the printed circuit board.

In some embodiments, the reinforcing plate is parallel to the printed circuit board; and/or the reinforcing plate is located between the support member and the printed circuit

In some embodiments, the display device further includes a first connecting member. The first connecting member is disposed in the accommodating cavity, and the printed circuit board is connected to the flexible display panel by the first connecting member.

In some embodiments, the first connecting member is provided with a chip thereon, and the support member is provided therein with a notch capable of accommodating the chip.

In some embodiments, a portion of a surface of the support member is engaged with at least a portion of the inner side of the shaft housing.

In some embodiments, in a cross section perpendicular to a length direction of the reel, a maximum dimension of the printed circuit board is equal to a maximum dimension of the accommodating cavity.

In some embodiments, the shaft housing is detachably connected to the support member. And/or, the shaft housing includes a first shaft housing and a second shaft housing, the first shaft housing is detachably connected to the second shaft housing, and the support member is detachably connected to the second shaft housing.

In some embodiments, the display device further includes a housing, a system mainboard and a second connecting member. The reel is located in the housing, and the system mainboard and the second connecting member are disposed in the housing. The system mainboard is connected to the printed circuit board by the second connecting member.

In some embodiments, a length of the second connecting member is larger than a distance between the printed circuit board and the system mainboard.

In some embodiments, the display device further includes a driving mechanism. The driving mechanism is connected to the reel and used for driving the reel to rotate.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a block diagram of a display device, in accordance with some embodiments of the present disclosure;

FIG. 2 is a diagram of a pixel driving circuit, in accordance with some embodiments of the present disclosure;

FIG. 3 is a diagram of another pixel driving circuit, in accordance with some embodiments of the present disclosure;

FIG. 4 is a structural diagram of a display device, in accordance with some embodiments of the present disclosure;

FIG. 5 is an unrolled diagram of a display device, in accordance with some embodiments of the present disclosure;

FIG. 6 is a rolled-up diagram of a display device, in accordance with some embodiments of the present disclosure;

FIG. 7 is a cross-sectional view taken along a section line B1-B2 in FIG. 4;

FIG. 8 is a structural diagram of a display device in the related art;

FIG. 9 is a structural diagram of a reel, in accordance with some embodiments of the present disclosure;

FIG. 10 is a three-dimensional diagram of a display device, in accordance with some embodiments of the present disclosure;

FIG. 11 is a structural diagram of a shaft casing, in accordance with some embodiments of the present disclosure;

FIG. 12 is a structural diagram of another reel, in accordance with some embodiments of the present disclosure;

FIG. 13 is a structural diagram of another reel, in accordance with some embodiments of the present disclosure;

FIG. 14 is a partial explosion diagram of a display device, in accordance with some embodiments of the present disclosure;

FIG. 15 is a structural diagram of another reel, in accordance with some embodiments of the present disclosure;

FIG. 16 is a structural diagram of another reel, in accordance with some embodiments of the present disclosure;

FIG. 17 is a partial structural diagram of a display device, in accordance with some embodiments of the present disclosure; and

FIG. 18 is a partial structural diagram of another display device, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” is construed as open and inclusive, i.e., “including, but not limited to”. In the description of the specification, the terms such as “one embodiment”, “some embodiments”, “exemplary embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

Embodiments of the present disclosure provide a retractable display device, such as a pull-out display device, which may change a size of a display screen during use.

The display device may be an electronic device with a function of displaying image (including a still image or a moving image, where the moving image may be a video). For example, the display device is any of a display, a television, a billboard, a digital photo frame, a laser printer having a display function, a telephone, a mobile phone, a personal digital assistant (PDA), a digital camera, a portable camcorder, a viewfinder, a navigator, a large-area wall, home appliance, an information search device (e.g., a business search device for a department of e-government, bank, hospital or electricity), a monitor, an electronic picture screen and a car display, and is not limited thereto.

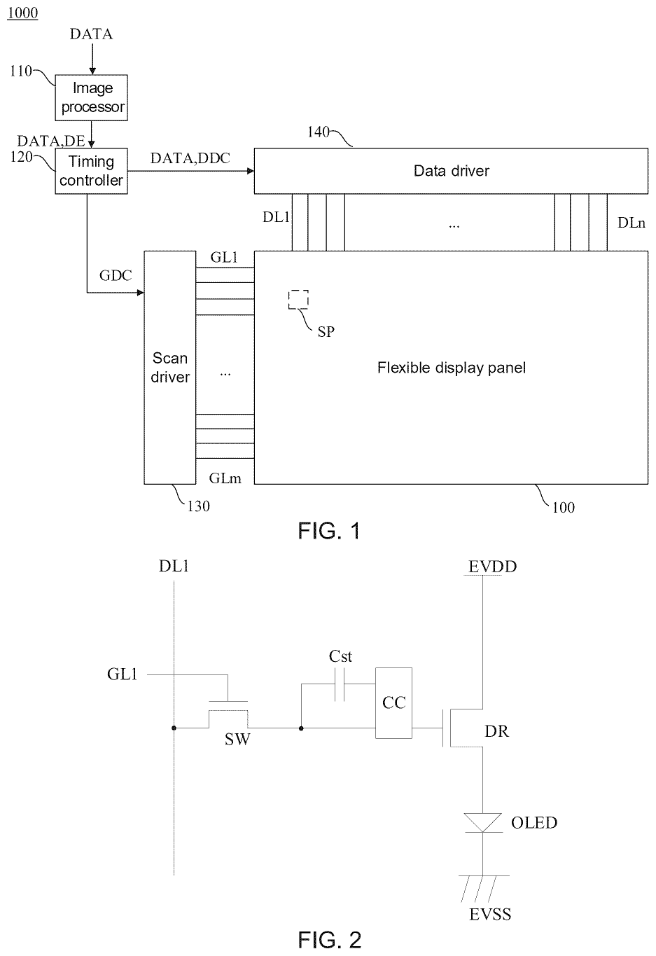

FIG. 1 is a block diagram of a display device in accordance with some embodiments of the present disclosure.

Referring to FIG. 1, the display device 1000 includes a flexible display panel 100, an image processor 110, a timing controller 120, a data driver 140 and a scan driver 130.

The image processor 110 outputs a data enable signal DE and an external data signal DATA provided. In addition to the data enable signal DE, the image processor 110 may further output a vertical synchronization signal, a horizontal synchronization signal, a clock signal and the like (not shown in FIG. 1).

The timing controller 120 receives the data enable signal DE and the data signal DATA from the image processor 110. The timing controller 120 may further receive the vertical synchronization signal, the horizontal synchronization signal, the clock signal and the like from the image processor 110. The timing controller 120 outputs, based on a driving signal, a gate timing control signal GDC for controlling operation timing of the scan driver 130 and a data timing control signal DDC for controlling operation timing of the data driver 140.

The data driver 140 samples in response to the data timing control signal DDC provided from the timing controller 120 and latches the data signal DATA received from the timing controller 120, and converts the signal into a gamma reference voltage and outputs the gamma reference voltage. The data driver 140 outputs data signals DATA through data lines DL1 to DLn. The data driver 140 may be formed in a form of an integrated circuit (IC).

The scan driver 130 outputs a scan signal in response to a change in a level of a gate voltage of the gate timing control signal GDC provided from the timing controller 120. The scan driver 130 outputs scan signals through scan lines GL1 to GLn. The scan driver 130 may be formed in a form of an IC or in a form of a gate-in-panel (GIP) on the flexible display panel 100.

The image processor 110 is coupled to the timing controller 120, and the timing controller 120 may be coupled to the data driver 140 and the scan driver 130.

The flexible display panel 100 is used to display images. The flexible display panel 100 is electrically connected to and attached to the image processor 110, the timing controller 120, the data driver 140, the scan driver 130, and the like (e.g., a power supply unit). The flexible display panel 100 displays an image in response to the data signal DATA and the scan signal respectively provided from the data driver 140 and the scan driver 130. The specific structure of the flexible display panel 100 will be described in detail below.

With continued reference to FIG. 1, the flexible display panel 100 includes sub-pixels SP for displaying images. The sub-pixel SP is the minimum unit for displaying images in the flexible display panel 100, and each sub-pixel SP may display a single color, for example, the sub-pixel SP is a first sub-pixel, a second sub-pixel or a third sub-pixel for respectively displaying red, green or blue. Each sub-pixel SP includes a light-emitting device and a pixel driving circuit for controlling the light-emitting device to emit light. That is to say, a sub-pixel SP corresponds to a pixel driving circuit. The pixel driving circuit may be configured to write a data signal in response to a scan signal received, and drive the light-emitting device to emit light through the electrical signal. The light-emitting device may be any of an organic light-emitting diode (OLED) device, a quantum dot light-emitting diode (QLED) device, an inorganic light-emitting diode (light-emitting diode, LED), or a tiny light-emitting diode (mini LED or micro LED). Embodiments of the present disclosure are exemplarily described by considering an example where the light-emitting device is an OLED.

FIG. 2 is a diagram of a pixel driving circuit in accordance with some embodiments of the present disclosure.

Referring to FIG. 2, the pixel driving circuit may include a switching transistor SW, a driving transistor DR and a capacitor Cst. The switching transistor SW is turned on in response to a scan signal provided by a first scan line GL1 to store a data signal, as a data voltage, provided by a first data line DL1 in the capacitor Cst. The driving transistor DR operates based on the data voltage stored in the capacitor Cst to allow a driving current to flow from a first power line EVDD and a second power line EVSS. The light-emitting device OLED emits light by a driving current formed by the driving transistor DR.

In some examples, the pixel driving circuit further includes a compensation circuit CC. The compensation circuit CC is a circuit provided in the pixel driving circuit for achieving compensation of a threshold voltage. The compensation circuit CC is composed of one or more transistors. The configuration of the compensation circuit CC varies widely depending on the compensation method, and an example will be described below.

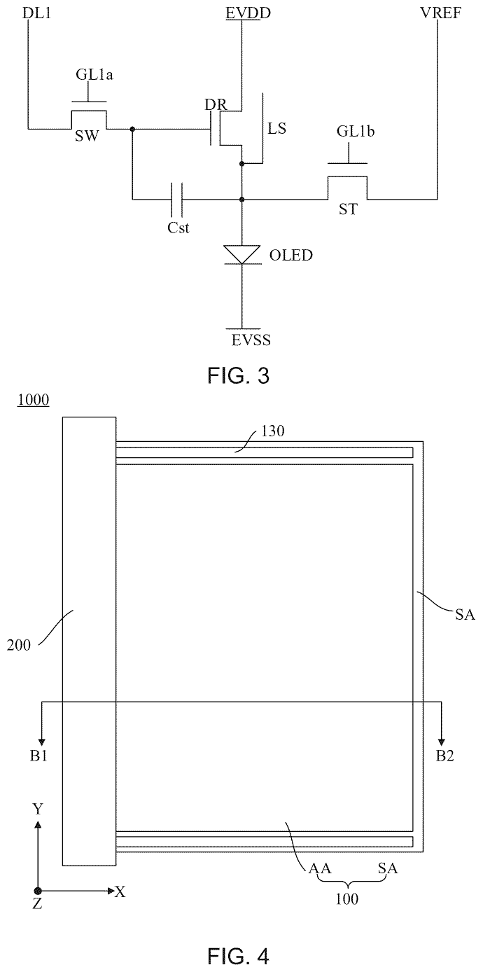

FIG. 3 is a diagram of another pixel driving circuit of a sub-pixel in accordance with some embodiments of the present disclosure.

The compensation circuit CC includes a sensing transistor ST and a sensing line VREF. Referring to FIG. 3, the sensing transistor ST is connected between a source line of the driving transistor DR and an anode (hereinafter referred to as a sensing node) of the organic light-emitting diode. The sensing transistor ST operates to provide a reset voltage (or a sensing voltage) through the sensing line VREF to the sensing node or sense a voltage or a current at the sensing node.

The switching transistor SW has a first electrode connected to the first data line DL1 and a second electrode connected to a gate of the driving transistor DR. The driving transistor DR has a first electrode connected to the first power line EVDD and a second electrode connected to the anode of the light-emitting device OLED. The capacitor Cst has a first electrode connected to the gate of the driving transistor DR and a second electrode connected to the anode of the light-emitting device. The light-emitting device OLED has the anode connected to the second electrode of the capacitor Cst and a cathode connected to the second power line EVSS. The sensing transistor ST has a first electrode connected to the sensing line VREF and a second electrode connected to the anode (i.e., the sensing node) of the light-emitting device OLED. It will be noted that a first electrode is one of a source and a drain of a transistor, and a second electrode is the other of the source and the drain of the transistor.

Depending on a compensation algorithm (or the configuration of the compensation circuit), an operation time of the sensing transistor ST may be similar to or the same as or different from an operation time of the switching transistor SW. In an example, the switch transistor SW may have a gate connected to the 1a-th scan line GL1a, and the sensing transistor ST may have a gate connected to the 1b-th scan line GL1b. In another example, the 1a-th scan line GL1a connected to the gate of the switching transistor SW and the 1b-th scan line GL1b connected to the gate of the sensing transistor ST may be connected such that they are shared.

The sensing line VREF may be connected to the data driver 140 (not shown in FIG. 3). In this case, the data driver 140 may sense the sensing nodes of the sub-pixels in real time during a non-display period of an image or an N-th frame period (N is an integer equal to or greater than 1) and perform compensation based on the sensing results. In addition, the switch transistor SW and the sensing transistor ST may be turned on at the same time. In this case, a sensing operation through the sensing line VREF and an output operation for outputting the data signal are distinguished based on a time-division method of the data driver 140.

A digital data signal, an analog data signal, or a gamma voltage may be compensated based on the sensing result. In addition, the compensation circuit that generates a compensation signal (or a compensation voltage) based on the sensing result may be implemented in the data driver 140, in the timing controller 120 (not shown in FIG. 3), or by a separate circuit.

The pixel driving circuit may include a plurality of transistors and a capacitor. For example, referring to FIG. 3, the pixel driving circuit includes a three-transistor-one-capacitor (3T1C) structure including the switching transistor SW, the driving transistor DR, the capacitor Cst and the sensing transistor ST, where T represents a transistor, and the number in front of T represents the number of transistors, C represents a capacitor, and the number in front of C represents the number of capacitors. In addition, in a case where the compensation circuit CC is added, the pixel driving circuit may be a 3T2C circuit, a 4T2C circuit, a 5T1C circuit, a 6T2C circuit or the like.

FIG. 4 is a structural diagram of a display device in accordance with some embodiments of the present disclosure.

For facilitating description of the following contents, an XYZ coordinate system is established. A first direction X and a second direction Y are both parallel to a plane where a display surface of the flexible display panel 100 is located, and intersect each other. For example, the first direction X and the second direction Y are perpendicular to each other. A third direction Z is perpendicular to the plane where the display surface of the flexible display panel 100 is located.

Referring to FIG. 4, the display device 1000 includes a flexible display panel 100 and a reel 200.

The flexible display panel 100 has a display area AA and a non-display area SA. The display area AA is an area of the flexible display panel 100 for displaying images, and a plurality of sub-pixels SP (not shown in FIG. 4) are arranged in the display area AA according to a specified rule. The non-display area SA is an area of the flexible display panel 100 other than the display area AA. The non-display area SA may be located on at least one side (e.g., one side or multiple sides) of the display area AA. For example, the non-display area SA may be disposed around the display area AA. In some examples, an edge separating the display area AA from the non-display area SA has pads, and pad electrodes electrically connected to signal lines in the display area AA are disposed on the pads.

In some examples, the scan driver 130 may be formed on the flexible display panel 100 through a gate in panel (GIP) technology. That is, the scan driver 130 may be formed on at least one side (e.g., upper and lower sides in FIG. 4) of the display area AA through the GIP technology.

The flexible display panel 100 may be folded or bent. In some examples, the flexible display panel 100 may be any of an organic light-emitting diode (OLED) display panel, a quantum dot light-emitting diode (QLED) display panel, and a tiny light-emitting diode (mini LED or micro LED) display panel.

The reel 200 may provide a mechanical structure for allowing the flexible display panel 100 to roll up around an outer periphery of the reel 200 and unroll from the reel 200. The reel 200 rotates about a rotation shaft extending in a length direction (the second direction Y) of the reel 200. The reel 200 is connected to the flexible display panel 100, and the flexible display panel 100 may be wound on the reel 200. The reel 200 rotates and drives the flexible display panel 100 to be rolled up or unrolled on the reel, so that the display device 1000 is retracted or expanded, so as to achieve the purpose of changing a size of a screen of the display device 1000 during use.

For example, a boundary of the flexible display panel 100 is in a shape of a rectangle, a length direction of the reel 200 is parallel to an edge of the flexible display panel 100 on a side thereof, and a direction of rolling up or unrolling the flexible display panel 100 is perpendicular to the length direction of the reel 200. For example, the flexible display panel 100 is rolled up or unrolled in the first direction X. In this way, an area of the flexible display panel 100 for display images may be uniformly changed, and thus a display effect of the display device 1000 may be improved.

In another implementation, the length direction of the reel 200 may not be parallel to the boundary of the flexible display panel 100.

The rolled-up and unrolled states of the flexible display panel 100 are described in detail below.

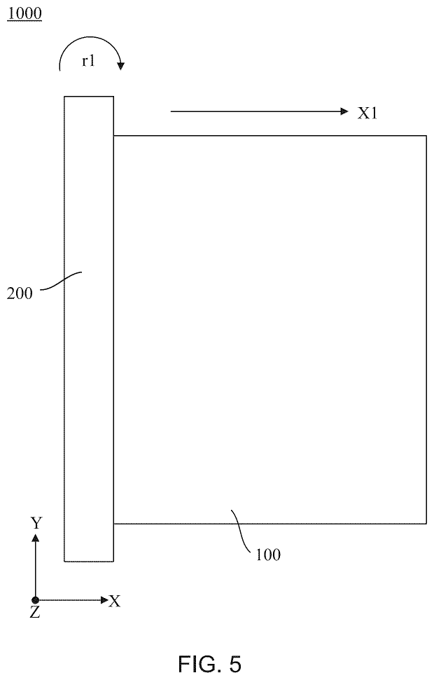

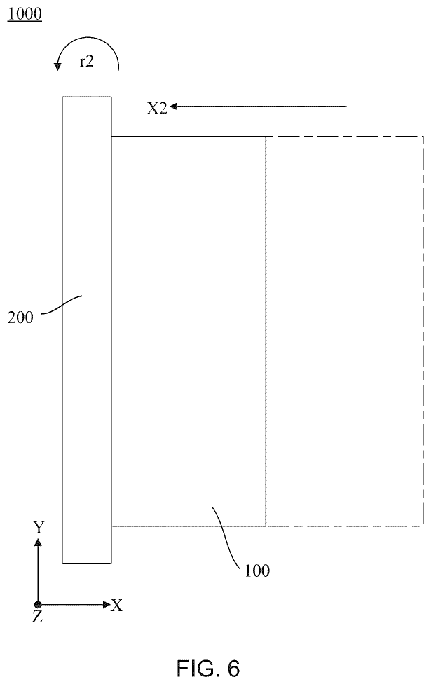

FIG. 5 is an unrolled diagram of a display device in accordance with some embodiments of the present disclosure. FIG. 6 is a rolled-up diagram of a display device in accordance with some embodiments of the present disclosure.

The flexible display panel 100 is rolled up or unrolled on the reel 200 as the reel 200 rotates. Referring to FIG. 5, when the reel 200 rotates along an r1 direction (e.g., a clockwise direction), the reel 200 rotates and drives the flexible display panel 100 to unroll on the reel 200, that is, a side of the flexible display panel 100 not connected to the reel 200 moves in a direction away from the reel 200 (an X1 direction). As the flexible display panel 100 is unrolled, the area for displaying images increases accordingly until the flexible display panel 100 is unrolled to an approximate plane. During this process, a screen of the display device 1000 expands.

Referring to FIG. 6, when the reel 200 rotates along an r2 direction (e.g., a counterclockwise direction), the reel 200 rotates and drives the flexible display panel 100 to be rolled up on the reel 200, that is, the side of the flexible display panel 100 not connected to the reel 200 moves in a direction toward the reel 200 (an X2 direction) and is wound on the reel 200. As the flexible display panel 100 is rolled up, the area for displaying images is reduced. During this process, the screen of the display device 1000 is retracted.

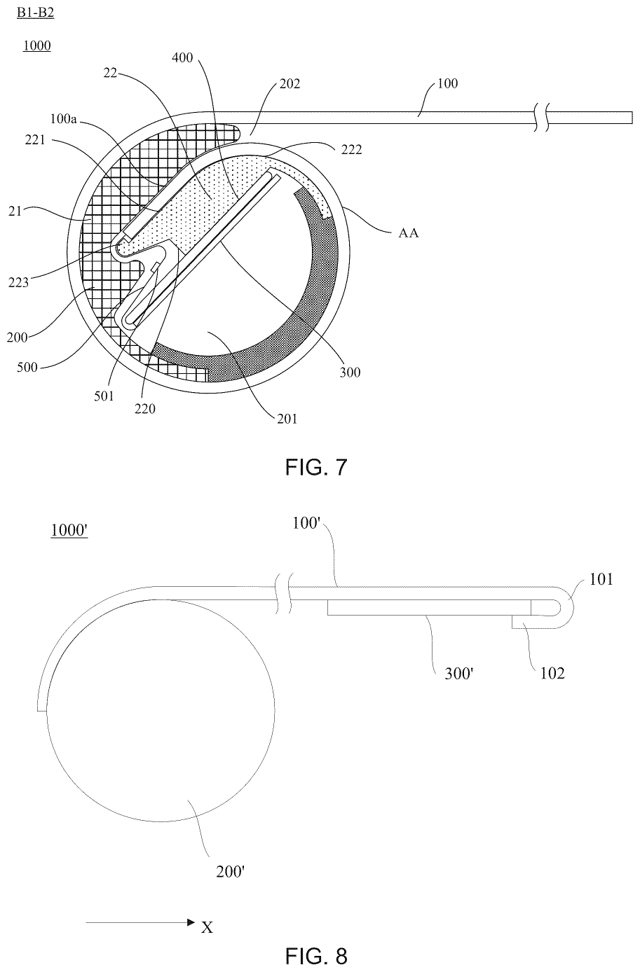

FIG. 7 is a cross-sectional view taken along a section line B1-B2 in FIG. 4.

In order to control the image displayed by the flexible display panel 100, the display device 1000 further includes a driving module. For example, the driving module includes an integrated driving circuit and a control circuit. The control circuit may transmit image data and a timing synchronization signal to the integrated driving circuit. The integrated driving circuit may generate a data signal and a driving signal that are used for displaying an image based on the image data and the timing synchronization signal, and transmit the data signal and the driving signal to the flexible display panel 100.

The control circuit is located in a printed circuit board (PCB) 300. The integrated driving circuit may be located in the printed circuit board 300, or formed in the flexible display panel 100 through the GIP technology, or located between the printed circuit board 300 and the flexible display panel 100. That is, referring to FIG. 7, the display device 1000 further includes a printed circuit board 300, and the printed circuit board 300 is connected to the flexible display panel 100.

The printed circuit board 300 includes a substrate and a plurality of electrical parts. The substrate cannot be bent or folded. A material of the substrate may be bakelite sheets, fiberglass board, or various types of plastic boards. The material of the substrate may be alternatively an adhesive sheet (prepreg) made by compressing an insulation portion, composed of glass fiber, polyester fiber, terylene fiber and resin, with epoxy resin and copper foil. The material of the substrate may alternatively be one of other suitable materials. The materials of the substrate will not be provided in detail in the embodiments of the present disclosure. In this way, the printed circuit board 300 is a rigid circuit board and cannot be rolled or folded.

The plurality of electrical parts are located on the substrate, and the substrate is further provided thereon with signal lines for sending and receiving electrical signals. The electrical parts may include the image processor 110 and the timing controller 120 (not shown in FIG. 7) described above, and further include a plurality of electronic elements such as capacitors, resistors, inductors, circulators, isolators, couplers, oscillators or transistors, but are not limited thereto.

FIG. 8 is a structural diagram of a display device in the related art.

In the related art, referring to FIG. 8, a printed circuit board 300′ is located outside a reel 200′. The printed circuit board 300′ may be located on a side (hereinafter referred to as a backlight surface of the flexible display panel 100′) of a flexible display panel 100′ away from a display surface. For example, the printed circuit board 300′ is located in an area corresponding to a display area of the flexible display panel 100′. As another example, the printed circuit board 300′ is located in an area corresponding to a non-display area of the flexible display panel 100′. As another example, the printed circuit board 300′ spans the areas corresponding to the display area and the non-display area of the flexible display panel 100′. The printed circuit board 300′ may also be located on a side of the flexible display panel 100′ away from the reel 200′.

As the reel 200′ rotates, the flexible display panel 100′ is rolled up or unrolled on the reel 200′. However, since the printed circuit board 300′ is a rigid circuit board and cannot be rolled, the printed circuit board 300′ cannot be wound on the reel 200′. When the flexible display panel 100′ is rolled up, an area of the flexible display panel 100′ corresponding to the printed circuit board 300′ cannot be wound on the reel 200′. In other words, the flexible display panel 100′ cannot be completely wound on the reel 200′, and there is a large area that cannot be retracted, which may affect the storage effect of the flexible display panel 100′.

Furthermore, referring to FIG. 8, in a case where the printed circuit board 300′ is located on the backlight surface of the flexible display panel 100′, a portion of the flexible display panel 100′ away from the reel 200′ has a bending area 101 and a bonding area 102. The bending area 101 is bent, so that the bonding area 102 is located on the backlight surface of the flexible display panel 100′. The bonding area 102 is connected to the printed circuit board 300′. The bending area 101 increases a dimension of the flexible display panel 100′ in the first direction X, resulting in an increase in a dimension of a frame of the display device 1000′ in the first direction X, which is not conducive to reduction in size of the display device 1000′. In a case where the printed circuit board 300′ is located on the side of the flexible display panel 100′ away from the reel 200′, since the frame of the display device 1000′ needs to cover the printed circuit board 300′, the dimension of the frame of the display device 1000′ in the first direction X increases, resulting in an increase in the size of the display device 1000′ as well, which is not conducive to reduction in size of the display device 1000′.

In order to solve the above problem, with continued reference to FIG. 7, in the embodiments of the present disclosure, the printed circuit board 300 is disposed in the reel 200, and the printed circuit board 300 and the flexible display panel 100 are connected to each other within the reel 200.

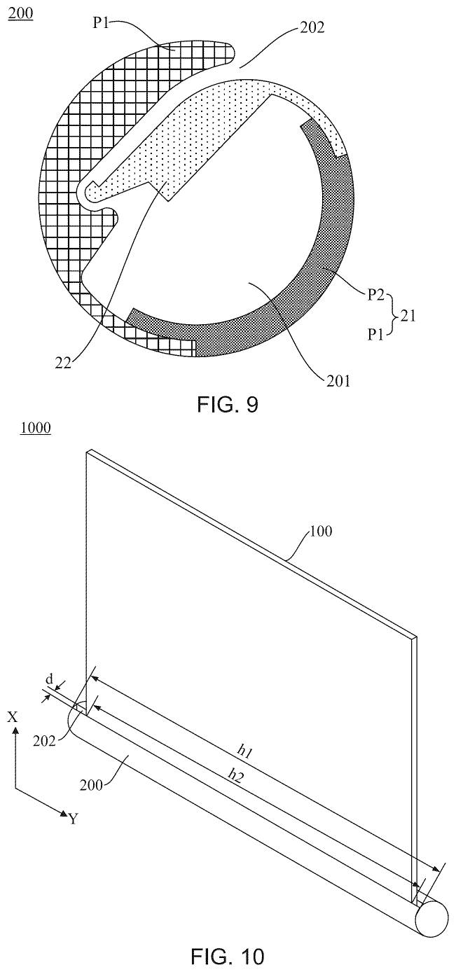

FIG. 9 is a structural diagram of a reel in accordance with some embodiments of the present disclosure. FIG. 10 is a three-dimensional diagram of a display device in accordance with some embodiments of the present disclosure.

Referring to FIGS. 9 and 10, the reel 200 has an accommodating cavity 201 and an opening 202, and the accommodating cavity 201 is in communication with the opening 202. A portion of the flexible display panel 100 is located inside the accommodating cavity 201, and the other portion thereof extends to an exterior of the accommodating cavity 201 through the opening 202. The opening 202 serves as a passage through which the portion of the flexible display panel 100 extends to the exterior of the accommodating cavity 201. For convenience of the following description, the portion of the flexible display panel 100 located inside the accommodating cavity 201 is referred to as a starting section.

Referring to FIG. 10, the opening 202 is a gap in an outer periphery of the reel 200. The opening 202 may be in a strip shape along the length direction (the second direction Y) of the reel 200, and an extension direction of the opening 202 is parallel to the length direction of the reel 200.

In some examples, a dimension h1 of the opening 202 in the length direction of the reel 200 is greater than a dimension h2 of the flexible display panel 100 in the length direction of the reel 200, and the flexible display panel 100 may extend smoothly out from the opening 202, thereby avoiding affecting the display effect of the display device due to wrinkles of the flexible display panel 100 generated at the opening 202.

In some examples, a width d of the opening 202 is greater than or equal to a thickness of the flexible display panel 100, so as to ensure that a portion of the flexible display panel 100 may extend from an interior of the accommodating cavity 201 of the reel 200 through the opening to an exterior of the reel 200. The width of the opening 202 is a dimension of the opening 202 in a direction perpendicular to the length direction of the reel 200, and the direction perpendicular to the length direction of the reel 200 and the length direction of the reel 200 are both parallel to a plane where the opening 202 is located.

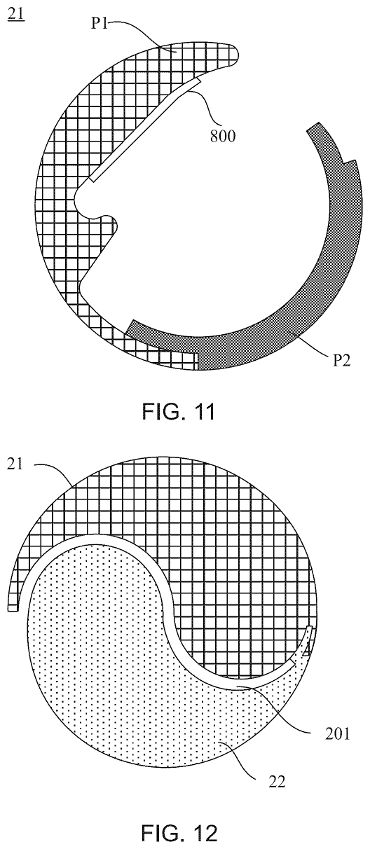

With continued reference to FIGS. 7 and 9, the reel 200 may include a shaft housing 21 and a support member 22. The support member 22 is connected to the shaft housing 21, and at least a portion of the support member 22 is opposite to an inner side of the shaft housing 21. The support member 22 is used to support the starting section 100a of the flexible display panel 100. FIG. 11 is a structural diagram of a shaft casing in accordance with some embodiments of the present disclosure.

For example, referring to FIG. 11, the inner side of the shaft housing 21 has a U-shaped structure. Referring to FIG. 9, an end of the shaft housing 21 and the support member 22 has a gap therebetween to form the opening 202, and the other end of the shaft housing 21 is connected to the support member 22. The shaft housing 21 has an accommodating space, and at least a portion (e.g., a portion or an entirety) of the support member 22 is located in the accommodating space. The inner side of the shaft housing 21 and a surface of the support member 22 not connected to the shaft housing 21 form the accommodating cavity 201.

The support member 22 covers a portion of the shaft housing 21, and thus the printed circuit board 300 (not shown in FIG. 9) may be prevented from falling off from the interior of the accommodating cavity 201 to the exterior of the reel 200. For example, referring to FIG. 9, a portion of the support member 22 extends into the accommodating space, and the other portion thereof is located outside the accommodating space. The portion of the support member 22 located outside the accommodating space is connected to an outer side of the shaft housing 21. In this case, an outer periphery of the reel 200 is the outer side of the shaft housing 21 and a portion of the support member 22. As another example, the support member 22 fully extends into the accommodating space, and the support member 22 is connected to the inner side of the shaft housing 21. In this case, the outer periphery of the reel 200 is the outer side of the shaft housing 21.

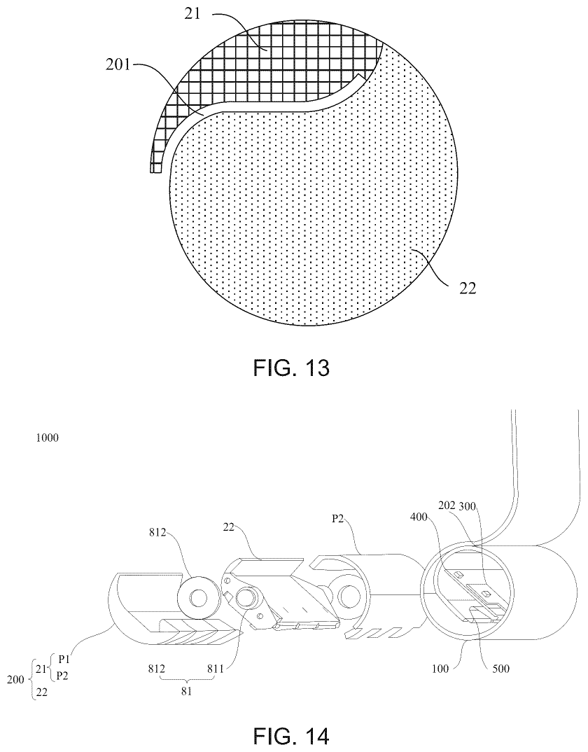

FIG. 12 is a structural diagram of another reel in accordance with some embodiments of the present disclosure. FIG. 13 is a structural diagram of yet another reel in accordance with some embodiments of the present disclosure.

For example, referring to FIGS. 12 and 13, the inner side of the shaft housing 21 has an S-shaped structure, the shaft housing 21 is opposite to the support member 22, and a side of the support member 22 opposite to the shaft housing 21 may also be in an S shape. As shown in FIG. 12, the S-shaped structure may be composed of two groups of 180° semicircular curved surfaces. As shown in FIG. 13, the S-shaped structure may be composed of two groups of 90° semicircular curved surfaces, alternatively, the S-shaped structure may be composed of 90° to 180° arcs. In this case, the inner side of the shaft housing 21 and an inner side of the support member 22 form the accommodating cavity 201.

The connection method between the support member 22 and the shaft housing 21 may be a fixed connection or a detachable connection. For example, the shaft housing 21 and the support member 22 are connected by an adhesive, where a material of the adhesive may include polyacrylate, polyurethane or epoxy resin. It will be noted that in actual applications, the material of the adhesive may also be one of other materials with good bonding properties, which are not listed here one by one. As another example, the shaft housing 21 and the support member 22 are connected by bolts. As another example, the shaft housing 21 and the support member 22 are each provided with an overlap position, and screw connection or adhesive connection is provided at the overlap position to assemble and connect the shaft housing 21 and the support member 22 into an entirety.

It can be understood that the connection method between the shaft housing 21 and the support member 22 may be any other connection method as long as the two may be connected.

The outer periphery of the reel 200 may be approximately circular. It can be understood that a cross-section of the reel 200 in the embodiments of the present disclosure may be in any shape, such as an ellipse or a polygon, as long as the flexible display panel 100 may be rolled up around the outer periphery of the reel 200.

With continued reference to FIG. 7, the starting section of the flexible display panel 100 is located inside the accommodating cavity 201, and the flexible display panel 100 extends from the interior of the accommodating cavity 201 through the opening 202 to the exterior of the accommodating cavity 201 and is wound around the outer periphery of the reel 200. The starting section of the flexible display panel 100 is connected to the support member 22, so that the flexible display panel 100 may be prevented from falling off from the reel 200.

The printed circuit board 300 is located in the accommodating cavity 201. For example, the printed circuit board 300 may not be connected to the inner side of the reel 200 and may be movably disposed in the accommodating cavity 201. As another example, the printed circuit board 300 is connected to the inner side of the reel 200, for example, the printed circuit board 300 is connected to the inner side of the shaft housing 21, as another example, the printed circuit board 300 is connected to a surface of the support member 22 extending into the accommodating cavity 201, as another example, the printed circuit board 300 is located on the inner side of the shaft housing 21 and the surface of the support member 22 extending into the accommodating cavity 201. The connection method may be a fixed connection or a detachable connection, reference may be made to the connection method mentioned above and details are not repeated here. The printed circuit board 300 is connected to the reel 200, thereby preventing the printed circuit board 300 from falling off and colliding with other structures.

The printed circuit board 300 is configured to be connected to the flexible display panel 100. For example, the printed circuit board 300 is directly connected to the flexible display panel 100. As another example, the printed circuit board 300 is connected to the flexible display panel 100 by a connecting member. The specific structure of the connecting member will be described in detail hereinafter.

The movement of the printed circuit board 300 in the embodiments of the present disclosure is restricted and limited within the reel 200, and thus a space utilization of the display device 1000 may be improved. When the flexible display panel 100 is rolled up, an area of the flexible display panel 100 corresponding to the printed circuit board 300 is located inside the reel 200, and a portion of the flexible display panel 100 exposed outside the reel 200 may be completely wound on the outer periphery of the reel 200, so that users cannot see the display area, thereby improving the storage effect of the flexible display panel 100. Moreover, in a case where the flexible display panel 100 is connected to the printed circuit board 300, the bonding area may be located in the accommodating cavity 201 of the reel 200. In this way, a portion of the flexible display panel 100 with the increased size in the first direction X is located in the accommodating cavity 201 of the reel 200, which actually relatively reduces a dimension of the flexible display panel 100 in the first direction X outside the reel 200, thereby achieving a narrow frame, which is conducive to the reduction in size of the display device 1000.

In some embodiments, with continued reference to FIG. 7, one side of the starting section of the flexible display panel 100 is connected to the support member 22, and the other side of the starting section of the flexible display panel 100 is connected to the inner side of the shaft housing 21. That is, both sides of the portion of the flexible display panel 100 located inside the accommodating cavity 201 are connected to the reel 200, and the connection method may be, for example, bonding. In this way, during rolling up or unrolling of the flexible display panel 100, both sides of the starting section may be subjected to tensile stress, so as to relieve the uneven stress on both sides of the flexible display panel 100 caused by tensile stress being provided on one side of the starting section and no stress being provided on the other side of the starting section, thereby preventing interlayer separation of the flexible display panel 100.

In some embodiments, a sealant may be provided on a side of the starting section of the flexible display panel 100 connected to the support member 22 to connect the starting section to the support member 22, and a sealant may be provided on another side of the starting section of the flexible display panel 100 connected to the inner side of the shaft housing 21 to connect the starting section to the inner side of the shaft housing 21. The sealant may include waterproof and vibration-proof polymer resin. In this case, part of the accommodating cavity 201 of the reel 200 is filled with the sealant and the flexible display panel 100, so as to block penetration of moisture and transmission of vibration, thereby preventing the flexible display panel 100 and the printed circuit board 300 that are located in the reel 200 from being damaged.

In some embodiments, with continued reference to FIG. 7, the support member 22 and the shaft housing 21 press at least a portion of the flexible display panel 100 located between the support member 22 and the shaft housing 21. For example, the support member 22 and the shaft housing 21 press the starting section of the flexible display panel 100. A distance between the inner side of the shaft housing 21 and the support member 22 that correspond to the starting section is equal to the thickness of the flexible display panel 100. The both sides of the flexible display panel are sandwiched between the support member and the shaft housing, and pressure is applied on both side, thereby relieving the problem of adjacent film layers of flexible display panels peeling off from each other under cutting stress.

In some embodiments, as shown in FIG. 11, a protective layer 800 is provided on the inner side of the shaft housing 21. The protection layer is at least provided opposite to the starting section of the flexible display panel. For example, the protective layer is provided on a whole of the inner side of the shaft housing 21. As another example, the protective layer is provided on a portion of the shaft housing 21 opposite to the starting section of the flexible display panel 100. A material of the protective layer is a soft energy-absorbing material, such as foam or thermoplastic polyurethane (TPU). In the embodiments, the soft energy-absorbing material may absorb external impacts. In this way, the protective layer may protect the flexible display panel 100. Moreover, the soft energy-absorbing material may be deformed, so as to prevent the flexible display panel 100 from being crushed due to the uneven inner side of the shaft housing 21.

In some embodiments, with continued reference to FIG. 7, a surface of the support member 22 proximate to the flexible display panel 100 includes a connection area 221 and a transition area 222. The connection area 221 is connected to the flexible display panel 100, and the connection area 222 is located at the opening 202. The flexible display panel 100 covers the connection area 221 and the transition area 222 sequentially, and is wound around an outside of the reel 200 through the opening 202. The connection area 221 is in a shape of a planar face or a curved face. For example, the connection area 221 is in a shape of a planar face, and the starting section of the flexible display panel 100 is parallel to the connection area 221, so that the pressing is tight. As another example, the connection area 221 is in a shape of a curved face, and a connection area between the starting section of the flexible display panel 100 and the connection area 221 increases, so that connection strength between the starting section and the connection area 221 may be improved.

In some embodiments, with continued reference to FIG. 7, the transition area 222 is in a shape of a curved surface, and the flexible display panel 100 is fitted with the transition area 222, so that the mechanical stress between the flexible display panel 100 and the transition area 222 may be reduced when the flexible display panel 100 is on the transition area 222. In this way, the flexible display panel 100 extends to the exterior of the reel 200 in a way of arc transition at the transition area 222, thereby avoiding affecting the use performance of the flexible display panel 100 due to a right-angle transition of the flexible display panel 100.

In some embodiments, with continued reference to FIG. 7, the outer side of the shaft housing 21 is in a shape of a curved face, so that an inner surface of the flexible display panel 100 is subjected to uniform force. A radius of curvature of the transition area is smaller than a radius of curvature of an outer surface (i.e., the outer side) of the shaft housing, that is, the curvature of the transition area is larger than the curvature of the shaft housing, thereby minimizing an increase in stress of the flexible display panel 100 in the transition area.

In some embodiments, with continued reference to FIG. 7, a surface of the support member 22 proximate to the flexible display panel 100 is provided with a protrusion 223 thereon, and an end of the flexible display panel 100 is located between the protrusion 223 and the opening 202. Thus, an area of the flexible display panel 100 extending into the accommodating cavity 201 may be reduced to increase an area of the display area outside the reel 200, thereby improving the display effect.

In some embodiments, with continued reference to FIG. 7, the starting section of the flexible display panel 100, the support member 22 and the printed circuit board 300 are stacked in sequence. The starting section of the flexible display panel 100, the support member 22 and the printed circuit board 300 form a stacked structure to minimize their volume, so that the starting section of the flexible display panel 100, the support member 22 and the printed circuit board 300 are compactly accommodated in the accommodating cavity 201, and the volume of the reel 200 may be reduced, which is conducive to the reduction in size of the display device 1000.

In some embodiments, the printed circuit board 300 is configured to be connected to the support member 22. The printed circuit board 300 may be directly connected to the support member 22, or may be indirectly connected to the support member 22 by one of other structures. For example, the printed circuit board 300 is connected to the surface of the support member 22. For example, the printed circuit board 300 may be fixed to the surface of the support member 22 by a fixing part, and the fixing part may constrain and limit the movement of the printed circuit board 300. The fixing part may include an adhesive such as a double-sided tape.

In some embodiments, at least a portion of the surface of the support member 22 is parallel to the printed circuit board 300, thereby enhancing the connection strength between the support member 22 and the printed circuit board 300.

In some embodiments, as shown in FIG. 7, the display device 1000 further includes a reinforcing plate 400 disposed on a side of the printed circuit board 300. The reinforcing plate 400 is used to enhance the strength of the printed circuit board 300 and prevent the printed circuit board 300 from being deformed by impact. A side of the reinforcing plate 400 is connected to the printed circuit board 300. The reinforcing plate 400 may be directly attached to a side of the printed circuit board 300, for example, the reinforcing plate 400 may be bonded to the printed circuit board 300 by a bonding member such as a double-sided tape. The reinforcing plate 400 may be provided corresponding to an entire area of the printed circuit board 300, or may be provided corresponding to some areas that need to be reinforced.

A material for forming the reinforcing plate 400 includes a metal material, for example, a metal with high density such as tungsten and iron, or stainless steel or an alloy material containing tungsten, iron and other metals. Of course, the reinforcing plate 400 may alternatively be made of a polymer material, and the polymer material is, for example, polyester, polyethylene, optically clear adhesive, pressure sensitive adhesive or other film materials. Limitations are not made in the present disclosure.

In some embodiments, the reinforcing plate 400 is parallel to the printed circuit board 300, and thus a contact area between the reinforcing plate 400 and the printed circuit board 300 may increase as much as possible, thereby enhancing the strength of the printed circuit board 300.

In some embodiments, the reinforcing plate 400 is located between the support member 22 and the printed circuit board 300, and a side of the reinforcing plate 400 is connected to the printed circuit board 300, and the other side thereof is connected to the support member 22. That is, the printed circuit board 300 is connected to the support member 22 through the reinforcing plate 400.

In some embodiments, in a cross section perpendicular to a length direction of the reel 200, a maximum dimension of the printed circuit board 300 is equal to a maximum dimension of the accommodating cavity 201. Here, the term “equal” means equality within a certain tolerance range. That is, the printed circuit board 300 is located at the widest part of the accommodating cavity 201 of the reel 200, so as to increase an area of the printed circuit board 300 as much as possible.

In some other embodiments, with continued reference to FIG. 7, the display device 1000 further includes a first connecting member 500. The first connecting member 500 is disposed in the accommodating cavity 201. The printed circuit board 300 is connected to the flexible display panel 100 by the first connecting member 500.

The first connecting member 500 may include an integrated driving circuit, and the integrated driving circuit may generate a data signal and a pixel driving signal that are used for displaying an image based on the image data and the timing synchronization signal, and transmit the data signal and the driving signal to the flexible display panel 100. The integrated driving circuit is separated from the printed circuit board 300 and the flexible display panel 100. In this way, it may avoid failure due to a high tensile stress of a chip on film (COF) area caused by directly fixing the COF area of the flexible display panel. It may also avoid bending an area where the integrated driving circuit is located toward the backlight surface, so as to avoid the integrated driving circuit being bent to the backlight surface, thereby avoiding pressure on the integrated driving circuit during rolling up and overcoming the problem of fragmentation and failure of the integrated driving circuit.

The first connecting member 500 may be a chip on film (COF) provided with a data driver thereon, but is not limited thereto. For example, the first connecting member 500 may be implemented through a tape carrier package (TCP) technology and connects the printed circuit board 300 and an end of the flexible display panel 100 located in the reel 200, so as to prevent or reduce the possibility of damage to the printed circuit board 300 due to repeated stress caused by rolling up and unrolling.

The first connecting member 500 may not be rigid, for example, the first connecting member 500 may be a flexible circuit board. The first connecting member 500 may be at least partially positioned in the accommodating cavity 201 in a bent shape.

In some embodiments, a limiting area is formed between the support member 22, the shaft housing 21 and the printed circuit board 300, and the first connecting member 500 may be located in the limiting area in a bendable manner. For example, a chip 501 may be disposed on the first connecting member 500. The support member 22 is provided therein with a notch 220 (as shown in FIG. 7) for accommodating the chip 501. In this case, the limiting area protects the chip 501 and prevents the chip 501 from falling and being damaged.

The first connecting member 500 may be bent multiple times at a position without the chip 501 provided, which is not limited in the present disclosure. For example, with continued reference to FIG. 7, an end of the first connecting member 500 is connected to the flexible display panel 100, a portion thereof is attached to the support member 22, and the other portion thereof is bent multiple times in the limiting area to be connected to the printed circuit board 300.

In this way, the first connecting member 500 with a long dimension may be accommodated in the accommodating cavity 201.

In some embodiments, with continued reference to FIG. 7, a portion of the surface of the support member 22 is engaged with at least a portion of the inner side of the shaft housing 21. For example, the surface of the support member 22 is provided with a first protrusion thereon, and the inner side of the shaft housing 21 is provided with a first groove therein. The first protrusion extends into the first groove, and the first protrusion and the first groove cooperate with each other to prevent the support member 22 and the shaft housing 21 from being separated in a direction perpendicular to the first protrusion.

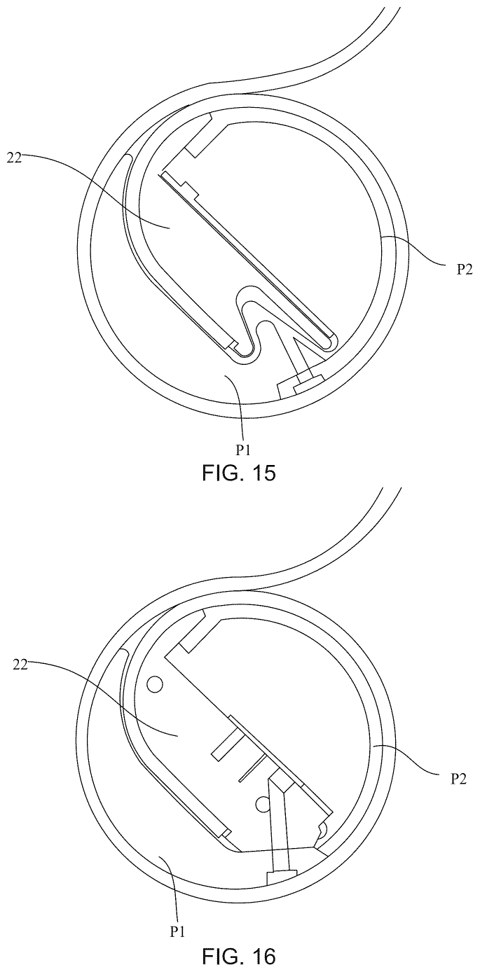

FIG. 14 is a partial explosion diagram of a display device in accordance with some embodiments of the present disclosure. FIG. 15 is a structural diagram of a reel in accordance with some embodiments of the present disclosure. FIG. 16 is a structural diagram of another reel in accordance with some embodiments of the present disclosure.

In some embodiments, referring to FIG. 14, the shaft housing 21 includes a first shaft housing P1 and a second shaft housing P2. The opening 202 is located at ends of the first shaft housing P1 and the second shaft housing P2, and the other ends of the first shaft housing P1 and the second shaft housing P2 are detachably connected. The support member 22 is detachably connected to the second shaft housing P2.

Example 1: a surface of the support member 22 opposite to the first shaft housing P1 is provided with a second protrusion thereon, the first shaft housing P1 is provided therein with a second groove matching with the second protrusion, and the second protrusion and the second groove are matched and connected with each other.

Example 2: the support member 22, the first shaft housing P1 and the second shaft housing P2 are each provided with an overlap position, and the support member 22, the first shaft housing P1 and the second shaft housing P2 are connected through the overlap positions.

Example 3: referring to FIG. 15, the first shaft housing P1 and the second shaft housing P2 are connected by screws; and the first shaft housing P1 and the support member 22 may also be connected by screws.

In some other embodiments, referring to FIG. 16, the support member 22 is overlapped with the second shaft housing P2, the first shaft housing P1 is connected to the support member 22 by screws, and the first shaft housing P1 is connected to the second shaft housing P2.

In the length direction (the second direction Y) of the reel 200, a connection position between the first shaft housing P1 and the second shaft housing P2 and a connection position between the first shaft housing P1 and the support member 22 may be in different cross-sections.

In some embodiments, the support member 22, the first shaft housing P1 and the second shaft housing P2 are each of an integral structure, which is easy for manufacture. The materials of the support member 22, the first shaft housing P1 and the second shaft housing P2 may be hard plastic, metal, or the like. The support member 22, the first shaft housing P1 and the second shaft housing P2 are profiled to form the reel 200 having the accommodating cavity 201 and the opening 202, and the molding method may be injection molding or computer numerical control (CNC) molding.

In some embodiments, the shaft housing 21 and the support member 22 are detachably connected. The connection method may refer to the connection method between the first shaft housing P1 and the second shaft housing P2 described above, and details are not repeated here.

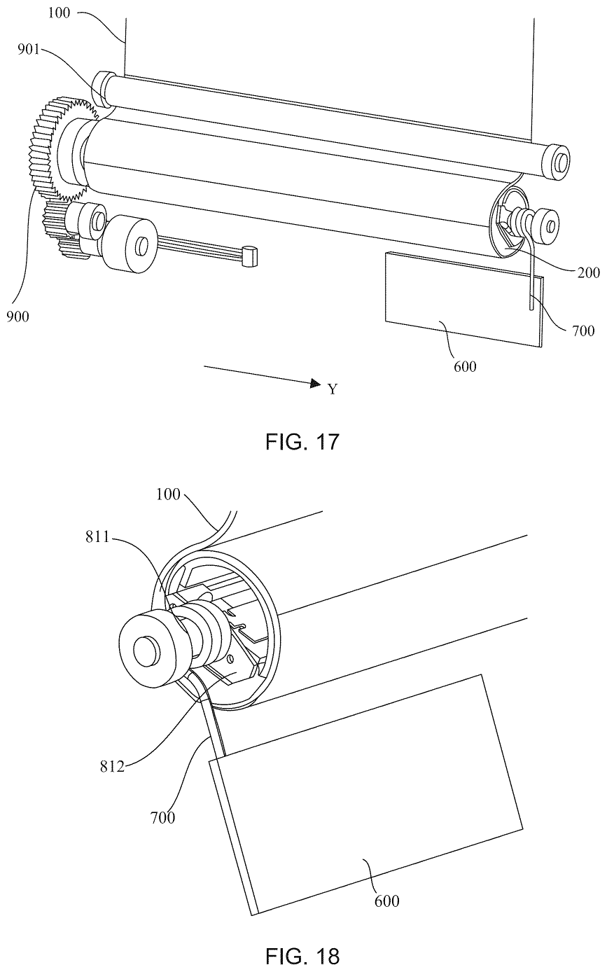

FIG. 17 is a partial structural diagram of a display device in accordance with some embodiments of the present disclosure. FIG. 18 is a partial structural diagram of another display device in accordance with some embodiments of the present disclosure.

In some embodiments, referring to FIGS. 17 and 18, the display device 1000 further includes a system mainboard 600. The system mainboard 600 is disposed outside the reel 200. The system mainboard 600 may be provided thereon with a power line for supplying power to each component and/or signal lines for transmitting and receiving electric signals. The printed circuit board 300 is connected to the system mainboard 600 by second connecting member(s) 700. In some examples, a plurality of second connecting members 700 may be provided. The system mainboard 600 may be connected to a supply unit to transmit signals and power for displaying images on the flexible display panel 100. The second connecting member 700 serves as a passage through which the printed circuit board 300 accommodated in the reel 200 is connected to an external structure such as the system mainboard 600.

The second connecting member 700 may be a shaft-connecting cable. One end of the shaft-connecting cable is connected to the printed circuit board 300, and the other end thereof is connected to the system mainboard 600. The bending degree of the shaft-connecting cable may be changed to maintain electrical connection between the printed circuit board 300 and the system mainboard 600. For example, the shaft-connecting cable may be formed by winding a plurality of signal lines, and a diameter of the shaft-connecting cable may be in a range of 1 mm to 5 mm, inclusive, such as 1 mm, 2 mm, 3 mm, 3.5 mm, 4 mm or 5 mm. The second connecting member 700 may alternatively be a flexible flat cable (FFC), and a thickness of the flexible flat cable is less than or equal to 0.2 mm, such as 0.2 mm or 0.1 mm. The thickness of the flexible flat cable cannot be too thick, otherwise a relatively large space in the accommodating cavity 201 will be occupied, which is not conducive to reducing the volume of the reel 200. The second connecting member 700 may also be one of other connecting members that may electrically connect the printed circuit board 300 and the system mainboard 600.

In some embodiments, one end of the shaft-connecting cable is connected to the printed circuit board 300, and the other end thereof is connected to the system mainboard 600 around a rotation shaft at least one turn. That is, a length of the second connecting member 700 is greater than a distance between the printed circuit board 300 and the system mainboard 600. As the flexible display panel 100 is rolled up and unrolled on the reel 200, the printed circuit board 300 rotates with the rotation of the reel 200, and a distance between the second connecting member 700 and a connection point between the printed circuit board 300 and the system mainboard 600 changes. Therefore, the second connecting member 700 is wound around the rotation shaft of the reel 200 at least one turn. In this way, as the flexible display panel 100 is rolled up and unrolled on the reel 200, the second connecting member 700 expands or retracts. The second connecting member 700 may compensate for a length difference between the flexible display panel 100 and the printed circuit board 300 caused by the rolling operation, thereby preventing the second connecting member 700 from being broken due to an excessively small length.

In some embodiments, with continued reference to FIG. 14, the display device 1000 further includes at least one shaft-connecting component 81. The shaft-connecting component 81 is disposed on an end of the reel 200. The shaft-connecting component 81 may include a rotation shaft 811 and connecting members 812. The rotation shaft 811 is connected to the connecting members 812. The connecting member 812 is connected to an end of the reel 200. The rotation shaft 811 rotates to drive the reel 200 to rotate.

Referring to FIG. 17, the second connecting member 700 passes through the connecting member 812 to connect the printed circuit board 300 installed inside the reel 200 and the system mainboard 600 disposed outside the reel 200. As the flexible display panel 100 is unrolled, the more the flexible display panel 100 is unrolled, the more turns the second connecting member 700 is wound around the rotation shaft 811.

In some embodiments, the display device 1000 further includes a housing (not shown in figures). The reel 200, the system mainboard 600 and the second connecting member 700 are all located in the housing, and the housing may be designed to be circular, elliptical, rectangular or polygonal in shape. The housing is provided therein with a strip-shaped groove extending along the second direction Y. The reel 200 is located in the housing. The strip-shaped groove is opposite to the opening 202 of the reel 200. The flexible display panel 100 extends out from the strip-shaped groove through the opening 202 and is wound on the reel 200.

In some embodiments, the reel 200 may be rotated by a physical force directly provided by a user.

In some embodiments, referring to FIG. 17, the display device 1000 further includes a driving mechanism 900. The driving mechanism 900 may be located within the housing. The driving mechanism 900 is connected to the reel 200 and drives the reel 200 to rotate, thereby driving the flexible display panel 100 to be rolled up or unrolled on the reel 200. The driving mechanism 900 may drive the reel 200 to rotate in response to a predetermined signal. The driving mechanism 900 is connected to the system mainboard 600. The system mainboard 600 transmits a signal to the driving mechanism 900, and the driving mechanism 900 drives the reel 200 to rotate.

For example, the driving mechanism 900 includes a first gear and a second gear. The first gear is located on a side of the reel 200 and is connected to the rotation shaft of the reel 200. The second gear is engaged with the first gear. The second gear rotates to drive the first gear to rotate, and thus drives the rotation shaft to rotate, so that the reel 200 rotates, thereby driving the flexible display panel 100 to be rolled up and unrolled on the reel 200. The second gear may be connected to a motor, and the motor drives the second gear to rotate. The driving mechanism 900 may also be one of other devices that can drive the reel 200 to rotate, and details are not described here.

In some embodiments, with continued reference to FIG. 17, the display device 1000 further includes a support rail 901. An extension direction of the support rail 901 is parallel to the length direction of the reel 200. The support rail 901 is located outside the reel 200 to support the flexible display panel 100. The support rail 901 may change an unrolling direction of the flexible display panel 100 to adapt to image display problems under various conditions.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

What is claimed is:

1. A display device, comprising:
a reel having an accommodating cavity and an opening, wherein the accommodating cavity and the opening are in communication; and the reel includes:
a shaft housing; and
a support member connected to the shaft housing; at least a portion of the support member being opposite to an inner side of the shaft housing;
a flexible display panel, wherein a starting section of the flexible display panel is located between the inner side of the shaft housing and the support member; the flexible display panel extends from an interior of the accommodating cavity through the opening to an exterior of the accommodating cavity and is wound around an outer side of the shaft housing; and the starting section of the flexible display panel is connected to the support member; and
a printed circuit board located in the accommodating cavity; the printed circuit board being connected to the flexible display panel.

2. The display device according to claim 1, wherein one side of the starting section of the flexible display panel is connected to the support member, and another side thereof is connected to the inner side of the shaft housing.

3. The display device according to claim 2, wherein the support member and the shaft housing press the starting section of the flexible display panel.

4. The display device according to claim 1, wherein the inner side of the shaft housing is provided with a protective layer thereon, and the protective layer is at least disposed opposite to the starting section of the flexible display panel.

5. The display device according to claim 1, wherein a surface of the support member proximate to the flexible display panel includes a connection area and a transition area; the connection area is connected to the flexible display panel, and the connection area is in a shape of a planar face or a curved face; the transition area is located at the opening, and the transition area is in a shape of a curved face.

6. The display device according to claim 5, wherein the outer side of the shaft housing is in a shape of a curved face, and a radius of curvature of the transition area is smaller than a radius of curvature of the outer side of the shaft housing.

7. The display device according to claim 1, wherein a surface of the support member proximate to the flexible display panel is provided with a protrusion thereon, and an end of the flexible display panel is located between the protrusion and the opening.

8. The display device according to claim 1, wherein the starting section of the flexible display panel, the support member and the printed circuit board are stacked in sequence.

9. The display device according to claim 8, wherein the printed circuit board is further connected to the support member.

10. The display device according to claim 8, further comprising:
a reinforcing plate disposed on a side of the printed circuit board.

11. The display device according to claim 1, further comprising:
a first connecting member disposed in the accommodating cavity, wherein the printed circuit board is connected to the flexible display panel by the first connecting member.

12. The display device according to claim 11, wherein the first connecting member is provided with a chip thereon, and the support member is provided therein with a notch capable of accommodating the chip.

13. The display device according to claim 1, wherein in a cross section perpendicular to a length direction of the reel, a maximum dimension of the printed circuit board is equal to a maximum dimension of the accommodating cavity.

14. The display device according to claim 1, wherein the shaft housing is detachably connected to the support member;
and/or
the shaft housing includes a first shaft housing and a second shaft housing, the first shaft housing is detachably connected to the second shaft housing, and the support member is detachably connected to the second shaft housing.

15. The display device according to claim 1, further comprising:
a housing, the reel being located in the housing;
a system mainboard disposed in the housing; and
a second connecting member disposed in the housing; the system mainboard being connected to the printed circuit board by the second connecting member.

16. The display device according to claim 15, wherein a length of the second connecting member is larger than a distance between the printed circuit board and the system mainboard.

17. The display device according to claim 15, further comprising:
a driving mechanism connected to the reel and for driving the reel to rotate.

18. The display device according to claim 1, wherein a dimension of the opening in a length direction of the reel is greater than a dimension of the flexible display panel in the length direction of the reel; and/or a width of the opening is greater than or equal to a thickness of the flexible display panel.

19. The display device according to claim 10, wherein the reinforcing plate is parallel to the printed circuit board; and/or the reinforcing plate is located between the support member and the printed circuit board.

20. The display device according to claim 1, wherein a portion of a surface of the support member is engaged with at least a portion of the inner side of the shaft housing.
